(19) United States
(12) Patent Application Publication
(10) Pub. No.: US 2009/0156006 A1
(43) Pub. Date: Jun. 18, 2009

(54) COMPOSITIONS AND METHODS FOR CMP OF SEMICONDUCTOR MATERIALS

(76) Inventors: Sriram Anjur, Aurora, IL (US); Jeffrey Dysard, St. Charles, IL (US); Paul Feeney, Aurora, IL (US); Timothy Johns, Naperville, IL (US); Richard Jenkins, Rochester, NY (US)

Correspondence Address: STEVEN WESEMAN;ASSOCIATE GENERAL COUNSEL, I.P., CABOT MICROELECTRONICS CORPORATION, 870 NORTH COMMONS DRIVE, AURORA, IL, 60504, US

(21) Appl. No.: 12/226,394

(22) PCT Filed: Apr. 30, 2007
(86) PCT No.: PCT/US2007/010446

§ 371 Date: Oct. 17, 2008

Related U.S. Application Data
(60) Provisional application No. 60/796,764, filed on May 2, 2006.

(51) Int. Cl. H01L 21/304; C09K 13/00

(52) U.S. Cl. 438/693; 252/79.1; 252/79.4; 257/E21.23

(57) ABSTRACT

The present invention provides a chemical-mechanical polishing (CMP) composition suitable for polishing semi-conductor materials. The composition comprises an abrasive, an organic amino compound, an acidic metal complexing agent and an aqueous carrier A CMP method for polishing a surface of a semiconductor material utilizing the composition is also disclosed.

### FIELD OF THE INVENTION

This invention relates to polishing compositions and methods for polishing a substrate using the same. More particularly, this invention relates to chemical-mechanical polishing compositions suitable for polishing semiconductor surfaces.

### BACKGROUND OF THE INVENTION

Compositions and methods for chemical-mechanical polishing (CMP) of the surface of a substrate are well known in the art. Polishing compositions (also known as polishing slurries, CMP slurries, and CMP compositions) for CMP of metal-containing surfaces of semiconductor substrates (e.g., integrated circuits) typically contain an abrasive, various additive compounds, and the like.

In general, CMP involves the concurrent chemical and mechanical polishing of an overlying first layer to expose the surface of a non-planar second layer on which the first layer is formed. One such process is described in U.S. Pat. No. 4,789,648 to Beyer et al. Briefly, Beyer et al., discloses a CMP process using a polishing pad and a slurry to remove a first layer at a faster rate than a second layer until the surface of the overlying first layer of material becomes coplanar with the upper surface of the covered second layer. A more detailed explanation of chemical mechanical polishing is found in U.S. Pat. No. 4,671,851, No. 4,910,155 and No. 4,944,836.

In conventional CMP techniques, a substrate carrier or polishing head is mounted on a carrier assembly and positioned in contact with a polishing pad in a CMP apparatus. The carrier assembly provides a controllable pressure to the substrate, urging the substrate against the polishing pad. The pad and carrier, with its attached substrate, are moved relative to one another. The relative movement of the pad and substrate serves to abrade the surface of the substrate to remove a portion of the material from the substrate surface, thereby polishing the substrate. The polishing of the substrate surface typically is further aided by the chemical activity of the polishing composition (e.g., by oxidizing agents or other additives present in the CMP composition) and/or the mechanical activity of an abrasive suspended in the polishing composition. Typical abrasive materials include silicon dioxide, cerium oxide, aluminum oxide, zirconium oxide, and tin oxide.

U.S. Pat. No. 5,527,423 to Neville, et al., for example, describes a method for chemically-mechanically polishing a metal layer by contacting the surface of the metal layer with a polishing slurry comprising high purity fine metal oxide particles suspended in an aqueous medium. Alternatively, the abrasive material may be incorporated into the polishing pad. U.S. Pat. No. 5,489,233 to Cook et al. discloses the use of polishing pads having a surface texture or pattern, and U.S. Pat. No. 5,958,794 to Bruxvoort et al. discloses a fixed abrasive polishing pad.

A semiconductor wafer typically includes a substrate, such as silicon or gallium arsenide, on which a plurality of transistors have been formed. Transistors are chemically and physically connected to the substrate by patterning regions in the substrate and layers on the substrate. The transistors and layers are separated by interlevel dielectrics (ILDs), comprised primarily of some form of silicon oxide (SiO₂). The transistors are interconnected through the use of well known multilevel interconnects. Typical multilevel interconnects are comprised of stacked thin-films consisting of one or more of the following materials: titanium (Ti), titanium nitride (TiN), tantalum (Ta), aluminum-copper (Al—Cu), aluminum-silicon (Al—Si), copper (Cu), tungsten (W), doped polysilicon (poly-Si), and various combinations thereof. In addition, transistors or groups of transistors are isolated from one another, often through the use of trenches filled with an insulating material such as silicon dioxide, silicon nitride, and/or polysilicon

The traditional technique for forming interconnects has been improved by the method disclosed in U.S. Pat. No. 4,789,648 to Chow et al. which relates to a method for producing coplanar multilevel metal/insulator films on a substrate. The new technique, which has gained wide interest and produces multilevel interconnects, uses chemical mechanical polishing to planarize the surface of the metal layers or thin-films during the various stages of device fabrication.

Although many of the known CMP slurry compositions are suitable for limited purposes, the slurries described above tend to exhibit unacceptable polishing rates and corresponding selectivity levels to insulator materials used in wafer manufacture. In addition, known polishing slurries tend to produce poor film removal traits for the underlying films or produce deleterious film-corrosion, which leads to poor manufacturing yields.

There is an ongoing need to develop new CMP compositions that exhibit useful removal rates for semiconductor materials such as polysilicon. The present invention provides such improved CMP compositions. These and other advantages of the invention, as well as additional inventive features, will be apparent from the description of the invention provided herein.

### BRIEF SUMMARY OF THE INVENTION

The present invention provides a chemical-mechanical polishing (CMP) composition suitable for polishing semiconductor materials including polysilicon. The composition has a neutral or basic pH (e.g., about 7 to about 9) and comprises about 0.1 to about 15 percent by weight of a particulate abrasive material, about 10 to about 5000 parts per million (ppm) of at least one organic amino compound, about 10 to about 5000 ppm of at least one acidic metal complexing agent, and an aqueous carrier therefor. The organic amino compound can be an amino alcohol compound, an alkoxylated amino compound, a polyamino compound, a quaternary amino compound, or a combination of two or more thereof.

Preferably, the particulate abrasive material is present in the composition in an amount in the range of about 1 to about 12 percent by weight, more preferably about 3 to about 6 percent by weight. The particulate abrasive material can be any abrasive material suitable for use in CMP compositions for polishing semiconductor materials (e.g., silica).

Preferably, the at least one organic amino compound is present in the composition in an amount in the range of about 50 to about 2000 ppm, more preferably about 100 to about 1000 ppm. In a particularly preferred embodiment, the at least one organic amino compound comprises 2-dimethylamino-2-methylpropanol (free base), a salt thereof, or a combination of the free base and a salt.

The at least one acidic metal complexing agent preferably is selected from the group consisting of dicarboxylic acids, polycarboxylic acids, aminocarboxylic acids, phosphates, polyphosphates, phosphonic acids, polymeric chelating agents, salts thereof, combinations of two or more of the foregoing, and the like. The at least one acidic metal complexing agent preferably is present in the composition in an amount in the range of about 50 to about 1000 ppm, more preferably about 100 to about 500 ppm.

In a preferred embodiment, the present invention provides a chemical-mechanical polishing composition, which has a neutral or basic pH, and comprises about 3 to about 6 percent by weight of amorphous silica (i.e., fumed silica), about 100 to about 1000 ppm of an organic amino compounds (e.g., 2-dimethylaniino-2-methylpropanol) and/or a salt thereof, about 100 to about 500 ppm of at least one acidic metal complexing agent, and an aqueous carrier such as water. Preferably, the at least one acidic metal complexing agent is selected from the group consisting of phosphoric acid, a dicarboxylic acid, a polycarboxylic acid, a phosphonic acid, a salt thereof, and a combination of two or more of the foregoing.

In another aspect, the present invention provides a chemical-mechanical polishing method for polishing a semiconductor substrate. The method comprises the steps of contacting a surface of a semiconductor substrate with a polishing pad and an aqueous CMP composition of the invention, and causing relative motion between the polishing pad and the substrate while maintaining a portion of the CMP composition in contact with the surface between the pad and the substrate for a time period sufficient to abrade at least a portion of the semiconductor surface. The CMP composition has a neutral or basic pH and comprises about 0.1 to about 15 percent by weight of a particulate abrasive material, about 10 to about 5000 ppm of at least one organic amino compound, about 10 to about 5000 ppm of at least one acidic metal complexing agent, and an aqueous carrier such as water. In a preferred embodiment, the CMP composition comprises about 1 to about 12 percent by weight, more preferably about 3 to about 6 percent by weight of an abrasive such as amorphous silica, about 50 to about 2000 ppm, more preferably about 100 to about 1000 ppm of an organic amino compound, about 50 to about 1000 ppm, more preferably 100 to about 500 ppm of at least one acidic metal complexing agent, and an aqueous carrier such as water. The at least one acidic metal complexing agent preferably is phosphoric acid, a dicarboxylic acid, a polycarboxylic acid, a phosphonic acid, a salt thereof, and a combination of two or more of the foregoing complexing agents.

### BRIEF DESCRIPTION OF THE DRAWINGS

FIG. 1 shows polysilicon, silicon nitride, and silicon oxide removal rates obtained from polishing of blanket wafers using various CMP compositions of the invention.

FIG. 2 illustrates the tunable selectivity of CMP compositions of the invention for removal of silicon nitride, polysilicon, and silicon oxides, obtained by varying the concentration of formulation that is applied to the substrate during CMP.

### DETAILED DESCRIPTION OF THE INVENTION

The present invention provides a CMP composition useful for polishing a semiconductor substrate. The CMP compositions contain an abrasive material, an organic amino compound, and an acidic metal complexing agent as described herein. The CMP compositions of the invention provide for even, rapid removal of polysilicon relative to conventional CMP compositions. In addition, the CMP compositions of the invention can be utilized in a manner in which the selectivity for removal of polysilicon, silicon oxide, and silicon nitride can be selected and varied by the user.

Abrasive materials useful in the CMP compositions of the invention include any abrasive material suitable for use in CMP of semiconductor materials. Examples of suitable abrasive materials include, without limitation silica, alumina, titania, ceria, zirconia, or a combination of two or more of the foregoing abrasives, which are well known in the CMP art. Preferred metal oxide abrasives include silica and alumina, most preferably silica (e.g., colloidal silica or amorphous silica). The abrasive material is present in the composition in an amount in the range of about 0.1 to about 15 percent by weight. Preferably, the abrasive material is present in the CMP composition in an amount in the range of about 1 to about 12 percent by weight, more preferably about 3 to about 6 percent by weight. The abrasive particles preferably have a mean particle size in the range of about 10 nm to about 500 nm, more preferably about 100 nm to about 200 nm, as determined by laser light scattering techniques, which are well known in the art.

The abrasive desirably is suspended in the CMP composition, more specifically in the aqueous component of the CMP composition. When the abrasive is suspended in the CMP composition, the abrasive preferably is colloidally stable. The term “colloid” refers to the suspension of abrasive particles in the liquid carrier. “Colloidal stability” refers to the maintenance of that suspension over time. In the context of this invention, an abrasive is considered colloidally stable if, when the abrasive is placed into a 100 ml graduated cylinder and allowed to stand without agitation for a time of 2 hours, the difference between the concentration of particles in the bottom 50 ml of the graduated cylinder ([B] in terms of g/ml) and the concentration of particles in the top 50 ml of the graduated cylinder ([T] in terms of g/ml) divided by the initial concentration of particles in the abrasive composition ([C] in terms of g/ml) is less than or equal to 0.5 (i.e., {[B]−[T]}/[C]≦0.5). The value of [B]-[T]/[C] desirably is less than or equal to 0.3, and preferably is less than or equal to 0.1.

As used herein and in the appended claims in reference to the compositions and methods of the invention, the term “organic amino compound” encompasses amino alcohols (e.g., 2-dimethylamino-2-methyl-l-propanol; 2-methylamino-2-methyl-1-propanol; 2-((2-((2-hydroxyethyl)amino)ethyl)amino)ethanol; N,N-bis(2-hydroxyethyl)ethylenediamine; 2-{[2-(dimethylamino)ethyl]methylamino}ethanol; 2,2-aminoethylaminoethanol; 2-(3-aminopropylamino)ethanol; 1-(2-hydroxyethyl)piperazine; 1,4-bis(2-hydroxyethyl)piperazine; choline; 2-(butylamino)ethanol; 2-(t-butylamino)ethanol; 2-(diisopropylamino)ethanol; triisopropanolamine; tris(hydroxymethylamino)ethane; N,N-diethanolamine; 2-amino-2-methyl-1-propanol; and the like), alkoxylated amines (e.g., 3-methoxypropylamine; bis(2-methoxyethyl)amine; and the like), polyamino compounds (e.g., N-propylethylenediamine; 2-((2-((2-hydroxyethyl)amino)ethyl)amino)ethanol; 2,2-aminoethylaminoethanol; 2-(3-aminopropylamino)ethanol; diethylenetriamine; and the like), quaternary ammonium hydroxides (e.g., substituted or unsubstituted tetralkylammonium hydroxides such as tetramethylammonium hydroxide; tetraethylammonium hydroxide; butyltrimethylammonium hydroxide; benzyltrimethylammonium hydroxide; choline; and the like) salts thereof, and combinations of two or more thereof.

As is evident from the foregoing examples, a given compound may be classified as either an amino alcohol, a polyamino compound, or both depending the number of amino groups present in the compound and the presence or absence of hydroxyl substituents. The amino alcohol and polyamino compounds include an amino group that can be a primary amino group, a secondary amino group, a tertiary amino group, a quaternary amino group, or a nitrogen-containing heterocyclic group Polyamino compounds include at least two amino functional groups, while amino alcohols include at least one hydroxyl group. The quaternary ammonium hydroxides can be added to the formulation as such, or can be generated in the formulation by reaction of a quaternary ammonium salt (e.g., a halide) with hydroxide ion.

A preferred amino alcohol compound is an N-methylated 2-amino-2-methylpropanol compound. As used herein, the term “N-methylated 2-amino-2-methypropanol compound” encompasses the free base of 2-methylamino-2-methypropanol, 2-dimethylamino-2-methyl propanol, a salt of either of the foregoing (e.g., a hydrochloride salt, a salt with the acidic metal complexing agent, such as a phosphate salt, an oxalate salt, and the like), and a combination of one or more free base materials and/or one or more salts. The CMP compositions of the invention can also include a trace amount of 2-amino-2-methylpropanol (i.e., the non-methylated amine), as well. Preferably, the majority of N-methylated 2-amino-2-methypropanol compounds present in the CMP compositions of the invention consist of 2-dimethylamino-2-methyl propanol and/or a salt thereof.

The CMP compositions of the invention comprise about 10 to about 5000 ppm of at least one organic amino compound. Preferably, the CMP composition comprises about 50 to about 2000 ppm of the organic amino compound, more preferably about 100 to about 1000 ppm.

As used herein and in the appended claims, the term “acidic metal complexing agent” encompasses a free acid compound, a salt compound, or a combination thereof, which can form a complex or chelate with a metallic ion present in the CMP composition or released into the composition during CMP of a semiconductor material.

Examples of suitable metal complexing agents include, without limitation, dicarboxylic acids (e.g., oxalic acid, malonic acid, succinic acid, maleic acid, phthalic acid, tartaric acid, aspartic acid, glutamic acid, and the like), polycarboxylic acids (e.g., citric acid, 1,2,3,4-butane tetracarboxylic acid, polyacrylic acid, polymaleic acid, and the like), aminocarboxylic acids (e.g., alpha-amino acids, beta amino acids, omega-amino acids, and the like), phosphates (e.g., phosphoric acid and salts thereof), polyphosphates (e.g., polyphosphoric acid and salts thereof), phosphonic acids e.g., amino phosphonates, phosphonocarboxylic acids, and the like), polymeric chelating agents, salts thereof, combinations of two or more of the foregoing, and the like.

Preferred acidic metal complexing agents include phosphoric acid, dicarboxylic acids (e.g., oxalic acid or succinic acid), polycarboxylic acids (e.g., citric acid), phosphonic acids, salts thereof, and combinations of two or more of the foregoing. Preferred phosphonic acid chelating agents include DEQUEST® 2000LC brand amino-tri(methylenephosphonic acid), and DEQUEST® 2010 brand hydroxyethylidene-1,1-diphosphonic acid, which are available from Solutia, salts of any of the foregoing, or a combination of two or more of the foregoing.

The acidic metal complexing agent is present in the composition in an amount in the range of about 10 to about 5000 ppm, preferably about 50 to about 1000, more preferably about 100 to about 500 ppm.

The CMP compositions of the invention optionally can include one or more oxidizing agent (e.g., to oxidize a component of the semiconductor surface, such as a metal component). Oxidizing agents suitable for use in the CMP compositions and methods of the present invention include, without limitation hydrogen peroxide, persulfate salts (e.g., ammonium monopersulfate, ammonium dipersulfate, potassium monopersulfate, and potassium dipersulfate), periodate salts (e.g., potassium periodate), salts thereof, and a combination of two or more of the foregoing. Preferably, the oxidizing agent is present in the composition in an amount sufficient to oxidize one or more selected metallic or semiconductor material present in the semiconductor wafer, as is well known in the semiconductor CMP art.

The CMP compositions of the invention can also optionally include suitable amounts of one or more other additive materials commonly included in CMP compositions, such as corrosion inhibitors, viscosity modifying agents, biocides, and the like.

In preferred embodiments, the CMP compositions further comprise a biocidal amount of a biocide (e.g., an isothiazolinone composition such as KATHON® biocide, available from Rohm and Haas).

The aqueous carrier can be any aqueous solvent, e.g., water, aqueous methanol, aqueous ethanol, a combination thereof, and the like. Preferably, the aqueous carrier is deionized water.

The CMP compositions of the invention preferably have a pH in the range of about 7 to about 9, more preferably about 7 to about 8. The CMP compositions can optionally comprise one or more pH buffering materials, for example, an acid such as hydrochloric acid, acetic acid, and the like, a base such as ammonia, sodium hydroxide, and the like, or a combination thereof, in addition to the other acidic and basic components of the composition (e.g., the organic amino compound and the acidic metal complexing agent).

The CMP compositions of the invention can be prepared by any suitable technique, many of which are known to those skilled in the art. The CMP composition can be prepared in a batch or continuous process. Generally, the CMP composition can be prepared by combining the components thereof in any order. The term “component” as used herein includes individual ingredients (e.g., abrasives, metal complexing agents, acids, bases, oxidizing agents, and the like), as well as any combination of ingredients. For example, an abrasive can be dispersed in water, and the metal complexing agent and the organic amino compound can be added, and mixed by any method that is capable of incorporating the components into the CMP composition. Typically, an oxidizing agent, when utilized, is not added to the CMP composition until the composition is ready for use in a CMP process, for example, the oxidizing agent can be added just prior to initiation of polishing. The pH can be adjusted at any suitable time.

The CMP compositions of the present invention also can be provided as a concentrate, which is intended to be diluted with an appropriate amount of aqueous solvent (e.g., water) prior to use. In such an embodiment, the CMP composition concentrate can include the various components dispersed or dissolved in aqueous solvent in amounts such that, upon dilution of the concentrate with an appropriate amount of aqueous solvent, each component of the polishing composition will be present in the CMP composition in an amount within the appropriate range for use.

The invention also provides a method of chemically-mechanically polishing a semiconductor substrate. The method comprises (i) contacting a surface of a substrate with a polishing pad and a CMP composition of the invention as described herein, and (ii) moving the polishing pad relative to the surface of the substrate with the polishing composition therebetween, thereby abrading at least a portion of the surface to polish the substrate.

The CMP methods of the present invention can be used to polish any suitable substrate, and is especially useful for polishing substrates comprising polysilicon, silicon nitride, silicon oxides, or combinations thereof. A particular advantage of the compositions and methods of the present invention is that the relative rates for removal of polysilicon compared to silicon oxides can be varied by varying the concentration of the composition applied to the surface of the substrate to be polished, while the silicon nitride removal rate remains relatively constant over a relatively broad concentration range. This “tunability” allows the polisher to select a formulation having a desired silicon nitride removal rate, and then vary the relative rates of polysilicon removal and silicon oxide removal as needed for the particular substrate being polished. The silicon nitride removal rate obtained when polishing a silicon nitride substrate with a CMP composition of the invention is primarily controlled by the concentration of the abrasive present in the formulation. Prior art compositions, such as those disclosed in U.S. Pat. No. 6,533,832 to Steckenrider et al. reportedly can provide some selectivity between polysilicon and silicon oxide removal, but do not afford adequate silicon nitride removal rates. This limitation of the prior art compositions is overcome by the CMP compositions of the present invention.

The present invention also provides method for selecting relative removal rates of polysilicon, silicon nitride, and silicon oxide in chemical-mechanical polishing of a substrate. The method comprises the steps of (a) polishing semiconductor substrates comprising polysilicon and silicon oxide with a predetermined concentration of an aqueous CMP composition of the invention, in which the CMP composition includes a predetermined concentration of abrasive sufficient to achieve a desired silicon nitride level during CMP of a silicon nitride substrate; (b) determining removal rates for polysilicon and silicon oxide achieved during step (a); (c) polishing semiconductor substrates comprising polysilicon and silicon oxide using a different concentration of the CMP composition than the concentration used in step (a); (d) determining removal rates for polysilicon and silicon oxide achieved during step (c); and (e) repeating steps (c) and (d) as needed, using different concentrations of the CMP composition, until a desired relative rate of polysilicon removal, silicone oxide removal, and silicon nitride removal is obtained.

The CMP methods of the present invention are particularly suited for use in conjunction with a chemical-mechanical polishing apparatus. Typically, the CMP apparatus comprises a platen, which, when in use, is in motion and has a velocity that results from orbital, linear, and/or circular motion, a polishing pad in contact with the platen and moving relative to the platen when in motion, and a carrier that holds a substrate to be polished by contacting and moving relative to the surface of the polishing pad. The polishing of the substrate takes place by the substrate being placed in contact with the polishing pad and a CMP composition of the invention and then moving the polishing pad relative to the substrate, so as to abrade at least a portion of the substrate to polish the substrate.

A substrate can be planarized or polished with a CMP composition of the invention using any suitable polishing pad (e.g., polishing surface). Suitable polishing pads include, for example, woven and non-woven polishing pads, grooved or non-grooved pads, porous or non-porous pads, and the like. Moreover, suitable polishing pads can comprise any suitable polymer of varying density, hardness, thickness, compressibility, ability to rebound upon compression, and compression modulus. Suitable polymers include, for example, polyvinylchloride, polyvinylfluoride, nylon, fluorocarbon, polycarbonate, polyester, polyacrylate, polyether, polyethylene, polyamide, polyurethane, polystyrene, polypropylene, coformed products thereof, and mixtures thereof

Desirably, the CMP apparatus further comprises an in situ polishing endpoint detection system, many of which are known in the art. Techniques for inspecting and monitoring the polishing process by analyzing light or other radiation reflected from a surface of the workpiece are known in the art. Such methods are described, for example, in U.S. Pat. No. 5,196,353 to Sandhu et al., U.S. Pat. No. 5,433,651 to Lustig et al., U.S. Pat. No. 5,949,927 to Tang, and U.S. Pat. No. 5,964,643 to Birang et al. Desirably, the inspection or monitoring of the progress of the polishing process with respect to a workpiece being polished enables the determination of the polishing end-point, i.e., the determination of when to terminate the polishing process with respect to a particular workpiece.

The following examples further illustrate the invention but, of course, should not be construed as in any way limiting its scope.

### EXAMPLE 1

This example illustrates formulations of CMP compositions according to the present invention.

The following CMP compositions were prepared by mixing a N-methylated 2-amino-2-methypropanol composition, an acidic metal complexing agent, and an aqueous slurry of fumed silica in a suitable amount of deionized water to afford compositions having the formulations set forth in Table 1. Each formulation also included about 10 ppm (on an actives basis) of a biocide (KATHON® biocide from Rohm and Haas). The pH of each composition was adjusted to the desired value by addition of aqueous ammonia and/or hydrochloric acid, as necessary.

TABLE 1
CMP compositions of the invention.

| Example # | Formulation |
|---|---|
| 1A | Fumed silica (5 wt %) |
| | 2-Dimethylamino-2-methylpropanol* (600 ppm) |
| | Phosphoric acid (200 ppm) |
| | Adjusted to pH 7.4 with ammonia and/or phosphoric |
| | acid as needed |
| 1B | Fumed silica (5 wt %) |
| | 2-Dimethylamino-2-methylpropanol* (600 ppm) |
| | Phosphoric acid (200 ppm) |
| | Adjusted to pH 8 with ammonia and/or phosphoric |
| | acid as needed |
| 1C | Fumed silica (5 wt %) |
| | 2-Dimethylamino-2-methylpropanol* (600 ppm) |
| | Oxalic acid (140 ppm) |
| | Adjusted to pH 7.4 with ammonia and/or oxalic as needed |
| 1D | Fumed silica (5 wt %) |
| | 2-Dimethylamino-2-methylpropanol* (600 ppm) |
| | Amino-tri(methylenephosphonic acid) (240 ppm) |
| | Adjusted to pH 7.4 with ammonia and/or the phosphonic |
| | acid as needed |

*DMAMP, which contained less than about 2% monomethylated and non-methylated amine

The above-described compositions were evaluated by polishing a polysilicon wafer on a benchtop polishing machine under the following polishing conditions: down-force of about 3 pounds per square inch (psi), platen speed of about 63 revolutions per minute (rpm), carrier speed of about 57 rpm, and a slurry feed rate of about 200 mL per minute (mL/min). Formulation IA afforded a polysilicon removal rate of about 1600 Angstroms-per-minute (Å/min). Formulation 1B afforded a polysilicon removal rate of about 1800 Å/min.

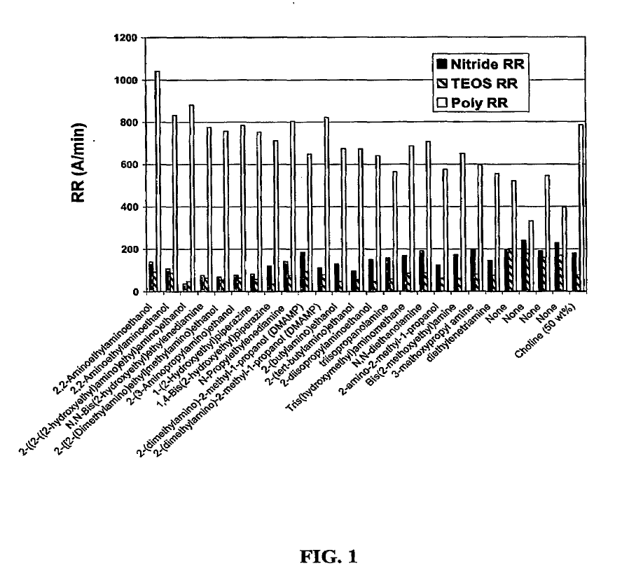

Additional formulations were prepared having a pH of about 8, about 12 percent by weight of fumed silica, about 200 ppm of phosphoric acid, and about 4.3 mmol/Kg (the molar equivalent of 500 ppm of DMAMP) of amino compound, wherein the 2-dimethylamino-2-methyl-1-propanol was replaced by a differed organic amino compound, i.e., 2-dimethylamino-2-methyl-1-propanol; 2-methylamino-2-methyl- 1-propanol; 2-((2-((2-hydroxyethyl)amino)ethyl)amino)ethanol; N,N-bis(2-hydroxyethyl)ethylenediamine; 2-{[2-(dimethylamino)ethyl]methylaminolethano}-ethanol; 2,2-aminoethylaminoethanol; 2-(3-aminopropylamino)ethanol; 1-(2-hydroxyethyl)piperazine; 1,4-bis(2-hydroxyethyl)piperazine; choline; 2-(butylamino)ethanol; 2-(t-butylamino)ethanol; 2-(diisopropylamino)ethanol; triisopropanolamine; tris(hydroxymethylamino)ethane; N,N-diethanolamine; 2-amino-2-methyl-1-propanol; 3-methoxypropylamine; bis(2-methoxyethyl)amine; N-propylethylenediamine; 2-((2-((2-hydroxyethyl)amino)ethyl)amino)ethanol; 2,2-aminoethylaminoethanol; 2-(3-aminopropylamino)ethanol; or diethylenetriamine. Each of these formulations was utilized to polish polysilicon, silicon nitride, and silicon oxide (borophosphosilicate glass, BPSG) blanket wafers. The polysilicon, silicon nitride, and silicon oxide removal rates obtained for each formulation are plotted in FIG. 1, compared to a formulation containing 2-dimethylamino-2-methyl-1-propanol. The data in FIG. 1 indicate that each of the formulations containing the different organic amino compounds provided acceptable removal rates for polysilicon, silicon nitride, and silicon oxide.

### EXAMPLE 2

This example illustrates the selectivity and tunability of CMP compositions of the invention for removal of polysilicon, silicon nitride, and silicon oxides.

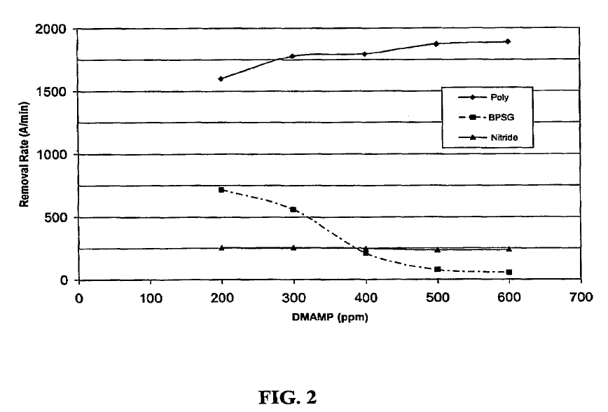

A CMP composition of the invention was prepared which comprised about 12 percent by weight fumed silica, about 600 ppm of 2-dimethylamino-2-methylpropanol (DMAMP), about 200 ppm of phosphoric acid in deionized water at about pH 8. The composition was serially diluted to effective DMAMP levels of 200 ppm, 300 ppm, 400 ppm and 500 ppm, and each dilution was evaluated by polishing polysilicon wafers, silicon nitride wafers, and BPSG wafers on a Mirra™ 3400 polishing machine (Applied Materials, Inc.) under the following polishing conditions: down-force of about 3 psi, platen speed of about 63 rpm, carrier speed of about 57 rpm, and a slurry feed rate of about 200 mL/min. The observed polysilicon, silicon nitride and silicon oxide (BPSG) removal rates at each dilution level are plotted in FIG. 2.

As is evident from the data shown in FIG. 2, the silicon nitride removal rate remained relatively constant at about 250 Å/min across the entire dilution range of 200 to 500 ppm (based on DMAMP). In contrast, the polysilicon removal rate steadily increased from about 1600 Å/min at 200 ppm to about 1900 Å/min at 500 ppm, whereas the silicon oxide removal rate decreased from about 750 Å/min at 200 ppm to about 100 Å/min at 500 ppm. These data demonstrate that the ratio of polysilicon removal to silicon oxide removal can be readily varied by adjusting the concentration of the polishing composition applied to the substrate, while maintaining a relatively constant silicon nitride removal rate.

Additional formulations were prepared, which included the same amounts of 2-dimethylamino-2-methylpropanol and phosphoric acid, but having a reduced level of abrasive, i.e., about 4 percent by weight fumed silica, about 5 percent by weight fumed silica, and about 6 percent by weight fumed silica. These formulations were evaluated as described above at dilution solids levels of about 600 ppm and about 100 ppm. The observed polysilicon, silicon nitride and silicon oxide removal rates at each dilution level evaluated are provided in Table 2.

The data in Table 2 indicate that silicon nitride removal rates increased with increasing concentration of silica abrasive in the slurries, while the polysilicon removal rates decreased as the formulation was diluted and the silicon oxide removal rates increased as the formulation was diluted. Accordingly, the CMP compositions of the invention provide a means of tuning the relative removal rates of polysilicon, silicon oxides, and silicon nitride by first selecting a formulation having a desired level of silicon nitride removal (e.g., based on the abrasive concentration in the slurry), and then varying the dilution level of the slurry to vary the ratio of polysilicon removal to silicon oxide removal until a desired balance between the polysilicon, silicon oxide, and silicon nitride removal rates is obtained.

TABLE 2

| | | | Silicon | |
|---|---|---|---|---|
| | | Polysilicon | Nitride | Polysilicon |
| | | Removal | Removal | Removal |
| | Dilution | Rate | Rate | Rate |
| Formulation | Level | Å/min | Å/min | Å/min |
| 2A (12% silica) | 1100 ppm | 2100 | 255 | 215 |
| 2A (12% silica) | 600 ppm | 1750 | 250 | 225 |
| 2B (6% silica) | 1100 ppm | 1900 | 150 | 170 |
| 2B (6% silica) | 600 ppm | 1750 | 150 | 175 |
| 2C (5% silica) | 600 ppm | 1600 | 125 | 145 |
| 2D (4% silica) | 1100 ppm | 1900 | 68 | 142 |
| 2D (4% silica) | 600 ppm | 1600 | 75 | 150 |

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. A chemical-mechanical polishing (CMP) composition comprising:
(a) about 0.1 to about 15 percent by weight of a particulate abrasive material;
(b) about 10 to about 5000 parts per million (ppm) of at least one organic amino compound;
(c) about 10 to about 5000 ppm of at least one acidic metal complexing agent; and
(d) an aqueous carrier therefor;
the composition having a neutral or basic pH.

2. The CMP composition of claim 1 wherein the particulate abrasive material is present in the composition in an amount in the range of about 3 to about 6 percent by weight.

3. The CMP composition of claim 1 wherein the particulate abrasive material comprises silica.

4. The CMP composition of claim 1 wherein the at least one organic amino compound comprises an amino alcohol compound, an alkoxylated amino compound, a polyamino compound, a quaternary ammonium hydroxide, a salt thereof, or a combination of two or more of the foregoing.

5. The CMP composition of claim 1 wherein the at least one organic amino compound comprises 2-dimethylamino-2-methylpropanol, a salt thereof, or a combination thereof.

6. The CMP composition of claim 1 wherein at least one organic amino compound is present in the composition in an amount in the range of about 50 to about 2000 ppm.

7. The CMP composition of claim 1 wherein at least one organic amino compound is present in the composition in an amount in the range of about 100 to about 1000 ppm.

8. The CMP composition of claim 1 wherein the at least one acidic metal complexing agent is selected from the group consisting of phosphoric acid, a dicarboxylic acid, a polycarboxylic acid, a phosphonic acid, a salt thereof, and a combination of two or more of the foregoing.

9. The CMP composition of claim I wherein the at least one acidic metal complexing agent is present in the composition in an amount in the range of about 100 to about 500 ppm.

10. The CMP composition of claim I further comprising a biocidal amount of a biocide.

11. A chemical-mechanical polishing (CMP) composition comprising:
(a) about 3 to about 6 percent by weight of amorphous silica;
(b) about 100 to about 1000 parts per million (ppm) of 2-dimethylamino-2-methylpropanol, a salt thereof, or a combination thereof;
(c) about 100 to about 500 ppm of at least one acidic metal complexing agent selected from the group consisting of phosphoric acid, a dicarboxylic acid, a polycarboxylic acid, a phosphonic acid, a salt thereof, and a combination of two or more of the foregoing; and
(d) an aqueous carrier therefor;
the composition having a neutral or basic pH.

12. A chemical-mechanical polishing (CMP) method for polishing a semiconductor substrate, the method comprising the steps of:
(a) contacting a surface of a semiconductor substrate with a polishing pad and an aqueous CMP composition, the CMP composition having a neutral or basic pH and comprising about 0.1 to about 15 percent by weight of a particulate abrasive material, about 10 to about 5000 parts per million (ppm) of at least one organic amino compound, about 10 to about 5000 ppm of at least one acidic metal complexing agent, and an aqueous carrier therefor; and
(b) causing relative motion between the polishing pad and the substrate while maintaining a portion of the CMP composition in contact with the surface between the pad and the substrate for a time period sufficient to abrade at least a portion of the semiconductor surface.

13. The CMP method of claim 12 wherein the particulate abrasive material is present in the composition in an amount in the range of about 3 to about 6 percent by weight.

14. The CMP method of claim 12 wherein the particulate abrasive material comprises silica.

15. The CMP method of claim 12 wherein the at least one organic amino compound comprises an amino alcohol compound, an alkoxylated amino compound, a polyamino compound, a quaternary ammonium hydroxide, a salt thereof, or a combination of two or more of the foregoing.

16. The CMP method of claim 12 wherein the at least one organic amino compound comprises 2-dimethylamino-2-methylpropanol, a salt thereof, or a combination thereof.

17. The CMP method of claim 12 wherein at least one organic amino compound is present in the composition in an amount in the range of about 50 to about 2000 ppm.

18. The CMP method of claim 12 wherein at least one organic amino compound is present in the composition in an amount in the range of about 100 to about 1000 ppm.

19. The CMP method of claim 12 wherein the at least one acidic metal complexing agent is selected from the group consisting of phosphoric acid, a dicarboxylic acid, a polycarboxylic acid, a phosphonic acid, a salt thereof, and a combination of two or more of the foregoing.

20. The CMP method of claim 12 wherein the at least one acidic metal complexing agent is present in the composition in an amount in the range of about 100 to about 500 ppm.

21. The method of claim 12 wherein the substrate comprises polysilicon, silicon nitride, and silicon oxide.

22. A chemical-mechanical polishing (CMP) method for selecting relative removal rates of polysilicon, silicon nitride and silicon oxide in CMP of a substrate, the method comprising the steps of:
(a) polishing semiconductor substrates comprising polysilicon and silicon oxide with a predetermined concentration of an aqueous CMP composition of claim 1, the CMP composition including a predetermined concentration of abrasive sufficient to achieve a desired silicon nitride level during CMP of a silicon nitride substrate;
(b) determining removal rates for polysilicon and silicon oxide achieved during step (a);
(c) polishing semiconductor substrates comprising polysilicon and silicon oxide using a different concentration of the CMP composition than the concentration used in step (a);
(d) determining removal rates for polysilicon and silicon oxide achieved during step (c); and
(e) repeating steps (c) and (d) as needed, using different concentrations of the CMP composition, until a desired relative rate of polysilicon removal, silicone oxide removal, and silicon nitride removal is obtained.
